(19) United States
(12) Patent Application Publication
(10) Pub. No.: US 2026/0057941 A1
(43) Pub. Date: Feb. 26, 2026

(54) NONVOLATILE MEMORY DEVICE AND OPERATION METHOD THEREOF

(71) Applicant: Samsung Electronics Co., Ltd., Suwon-si (KR)

(72) Inventors: Younghwi Yang, Suwon-si (KR); Kwangho Choi, Suwon-si (KR)

(21) Appl. No.: 19/275,896

(22) Filed: Jul. 21, 2025

(30) Foreign Application Priority Data
Aug. 23, 2024 (KR) 10-2024-0113564

(51) Int. Cl. G11C 16/10; G11C 16/04; G11C 16/08; G11C 16/30

(52) U.S. Cl. CPC G11C 16/102; G11C 16/0433; G11C 16/08; G11C 16/30

(57) ABSTRACT

The present disclosure relates to nonvolatile memory devices. An example nonvolatile memory device comprises a first string and a row decoder. The first string includes a plurality of memory transistors, a first non-memory transistor and a second non-memory transistor. The row decoder is configured to control a plurality of word lines respectively connected to the plurality of memory transistors, and first and second non-memory transistor control lines respectively connected to the first and second non-memory transistors. The row decoder is configured to decrease a voltage level of the first non-memory transistor control line at a first time point within a first time period during which a program voltage is provided to a word line of the plurality of word lines, and to decrease a voltage level of the second non-memory transistor control line at a second time point within the first time period.

### CROSS-REFERENCE TO RELATED APPLICATION

This application claims priority to and the benefit of Korean Patent Application No. 10-2024-0113564 filed in the Korean Intellectual Property Office on Aug. 23, 2024, the entire contents of which are incorporated herein by reference.

### BACKGROUND

A flash memory is widely used as a large-capacity storage medium in computing systems. The flash memory may include a plurality of strings sharing a plurality of word lines. As the plurality of strings share the word lines, in order to prevent the threshold voltage of the memory cell from being changed which is included in the string to be program-inhibited (hereinafter it will be referred to as an inhibit string), a self-boosting scheme may be applied to the inhibit string. For example, when the string selection transistor and the ground selection transistor included in the inhibit string are turned off, the channel voltages of memory cells included in the inhibit string may be boosted based on the voltage levels of the word lines.

However, with the recent trend of downsizing and high integrity of flash memory, there is a problem caused by boost leakage. More specifically, a problem has occurred in which charges charged in the channel of the memory cells included in the inhibit string are unintentionally leaked. In this case, data stored in the inhibit string may be unintentionally damaged.

### SUMMARY

The present disclosure relates to a nonvolatile memory device with minimized boost leakage and an operation method thereof.

In general, according to some aspects, a nonvolatile memory device includes a first string including a plurality of memory transistors, and first and second non-memory transistors; and a row decoder configured to control a plurality of word lines respectively connected to the plurality of memory transistors, and first and second non-memory transistor control lines respectively connected to the first and second non-memory transistors, wherein the row decoder is configured to decrease a voltage level of the first non-memory transistor control line at a first time point within a first time period during which a program voltage is provided to one of the plurality of word lines, and to decrease a voltage level of the second non-memory transistor control line at a second time point within the first time period.

In general, according to some aspects, a nonvolatile memory device includes: an inhibit string connected to a plurality of word lines, a plurality of non-memory transistor control lines, and a first bit line; a program string connected to the plurality of word lines, the plurality of non-memory transistor control lines, and a second bit line; and a row decoder configured to decrease a voltage level of a victim non-memory transistor control line, which is one of the plurality of non-memory transistor control lines, below a ground voltage, at a first time point within a first time period during which a program operation is performed on a target memory transistor included in the program string.

In general, according to some aspects, an operation method of a nonvolatile memory device is configured to program-inhibit a first string connected to a bit line, a plurality of word lines, and a plurality of non-memory transistor control lines. The operation method may comprise setting up the bit line and the plurality of non-memory transistor control lines; providing a program voltage to a target word line, which is one of the plurality of word lines; reducing a voltage level of a victim non-memory transistor control line, which is one of the plurality of non-memory transistor control lines, to a ground voltage; and reducing a voltage level of an aggressor non-memory transistor control line, which is one of the plurality of non-memory transistor control lines, to the ground voltage.

### BRIEF DESCRIPTION OF THE DRAWINGS

FIG. 1 illustrates a block diagram of an example of a storage device.

FIG. 2 illustrates an example detailed block of a nonvolatile memory device of FIG. 1.

FIG. 3 illustrates an example detailed diagram of a part of configuration of a memory cell array of FIG. 2.

FIG. 4 is an example diagram illustrating a self-boosting scheme applied to an inhibit string of FIG. 3 and a boost leakage phenomenon in more detail.

FIG. 5 illustrates an example of a program inhibit based on a boost retention logic in more detail.

FIG. 6 illustrates a detailed timing diagram of an example operation of a nonvolatile memory device.

FIG. 7 illustrates example program inhibit performance.

FIG. 8 illustrates a flowchart of an example operation of the nonvolatile memory device of FIG. 2.

FIG. 9 illustrates an example detailed diagram of a part of configuration of a memory cell array of FIG. 2.

FIG. 10 illustrates an example detailed timing diagram of an operation of a nonvolatile memory device.

FIG. 11 illustrates a flowchart of an example operation of the nonvolatile memory device of FIG. 10.

### DETAILED DESCRIPTION

Hereinafter, implementations will be described in detail and clearly to such an extent that one skilled in the art easily carries out the present disclosure. The details such as components and structures described in the specification are merely provided to assist the overall understanding of implementations. Therefore, it should be apparent to those skilled in the art that various changes and modifications of implementations described herein may be made without departing from the scope and spirit of the present disclosure. Moreover, the descriptions of well-known functions and structures are omitted for the sake of clarity and brevity. In the following drawings or in the detailed description, components may be connected to any other components except for components that are illustrated in drawings or are described in the detailed description. The terms described below are terms defined in consideration of the functions and are not limited to a specific function. The definitions of the terms should be determined based on the contents throughout the specification.

Components that are described in the detailed description with reference to the terms “driver”, “controller”, “block”, etc. may be implemented with software, hardware, or a combination thereof. For example, the software may be a machine code, firmware, an embedded code, and application software. For example, the hardware may include an electrical circuit, an electronic circuit, a processor, a microprocessor, a computer, integrated circuit cores, a pressure sensor, an inertial sensor, a microelectromechanical system (MEMS), a passive element, or a combination thereof.

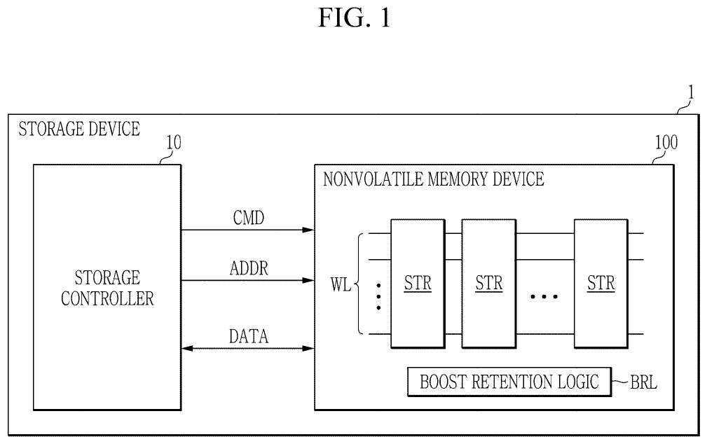

FIG. 1 illustrates a block diagram of an example of a storage device. Referring to FIG. 1, a storage device 1 may include a storage controller 10 and a nonvolatile memory device 100.

The storage controller 10 may store data DATA in the nonvolatile memory device 100 or read the data DATA stored in the nonvolatile memory device 100. For example, the storage controller 10 may transmit a command CMD and an address ADDR to the nonvolatile memory device 100 to store the data DATA in the nonvolatile memory device 100 or read the data DATA stored in the nonvolatile memory device 100.

Hereinafter, it is assumed that the storage device 1 is a solid state drive (SSD) and the nonvolatile memory device 100 is a flash memory device. However, the scope of the present disclosure is not limited thereto.

The nonvolatile memory device 100 may include a plurality of strings STR sharing a plurality of word lines WL. Each of the plurality of strings STR may include a plurality of memory cells. The plurality of memory cells may store data DATA provided from the storage controller 10. For example, the nonvolatile memory device 100 may program the data DATA into the plurality of strings STR (more specifically, a plurality of memory cells) based on the command CMD and the address ADDR provided from the storage controller 10, or may provide the data DATA stored in the plurality of strings STR to the storage controller 10.

When the nonvolatile memory device 100 programs data into some strings STR, the nonvolatile memory device 100 may inhibit (or program inhibit) the other strings STR to prevent the memory cells included therein from being unintentionally programmed. For example, the nonvolatile memory device 100 may program-inhibit a string to be not programmed (hereinafter referred to as an inhibit string STR_IHB) based on a self-boosting scheme.

As a more detailed example, the nonvolatile memory device 100 may increase (that is, boost) the channel voltage of memory cells included in the inhibit string STR_IHB based on the voltages of the plurality of word lines WL. In this case, even if a high voltage (for example, a program voltage) is applied to a certain word line WL, data may not be programmed to the inhibit string because the difference between the gate voltage and the channel voltage for the memory cell connected to the word line is small enough.

However, a phenomenon in which the channel voltage of the memory cells included in the inhibit string STR_IHB is unintentionally decreased may occur. For example, a boost leakage phenomenon in which charges charged in the channel of the memory cells included in the inhibit string STR_IHB leak may occur. In this case, the difference between the voltage applied to the gate of the memory cell connected to the word line where the program voltage is applied, and the channel voltage may unintentionally increase. Therefore, the memory cell may be unintentionally programmed, and the program inhibit for the inhibit string STR_IHB may fail. In this case, it may be difficult to guarantee the reliability of data stored in the inhibit string STR_IHB.

The nonvolatile memory device 100 may operate based on a boost retention logic BRL. The nonvolatile memory device 100 may reduce (or minimize) the boost leakage phenomenon based on the boost retention logic BRL. For example, the nonvolatile memory device 100 may strongly block a path through which charges leak from the channel of the memory cells included in the inhibit string STR_IHB based on the boost retention logic BRL. In this case, the phenomenon of data being unintentionally programmed into the inhibit string STR_IHB may be reduced, and thus the reliability of data stored in the nonvolatile memory device 100 may be improved. A specific operation method of the nonvolatile memory device 100 based on the boost retention logic BRL will be described in more detail below.

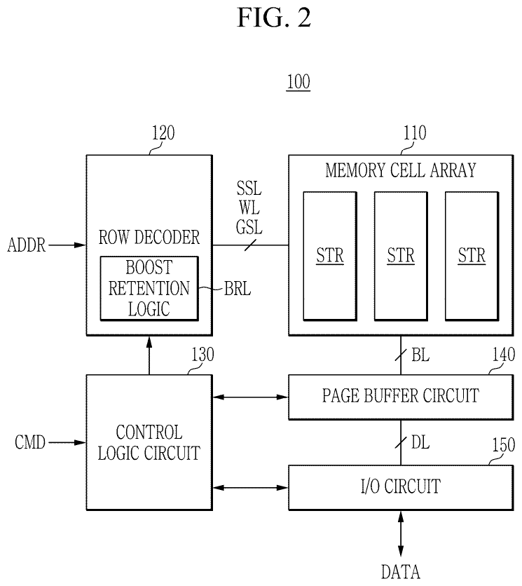

FIG. 2 illustrates an example detailed block of the nonvolatile memory device of FIG. 1. Referring to FIG. 1 and FIG. 2, the nonvolatile memory device 100 may include a memory cell array 110, a row decoder 120, a control logic circuit 130, a page buffer circuit 140, and an input/output circuit 150.

For a more concise description below, FIG. 2 illustrates that various signals, such as a command CMD, an address ADDR, and data DATA, are directly provided to various functional blocks (for example, the row decoder 120, the control logic circuit 130, and the input/output circuit 150). However, the scope of the present disclosure is not limited to the specific method in which the command CMD, the address ADDR, and the data DATA are transmitted between the storage controller 10 and the nonvolatile memory device 100.

The memory cell array 110 may include a plurality of strings STR. The plurality of strings STR may include a plurality of memory cells. The plurality of strings STR may be connected to different bit lines BL each other. The plurality of strings STR may share string selection lines SSL, word lines WL, and ground selection lines GSL.

The row decoder 120 may be connected to the memory cell array 110 through the string selection lines SSL, the word lines WLs, and the ground selection lines GSL. The row decoder 120 may receive the address ADDR from the storage controller 10. The row decoder 120 may decode the address ADDR and control voltage levels of the string selection lines SSL, the word lines WL, and the ground selection lines GSL based on the decoded result.

The row decoder 120 may operate based on the boost retention logic BRL. For example, the row decoder 120 may decrease the voltage level of the string selection line SSL below the ground voltage based on the boost retention logic BRL. In this case, since the amount of charges discharged from the channel of the memory cells included in the inhibit string STR_IHB to the bit line may be minimized, the boost leakage phenomenon may be minimized.

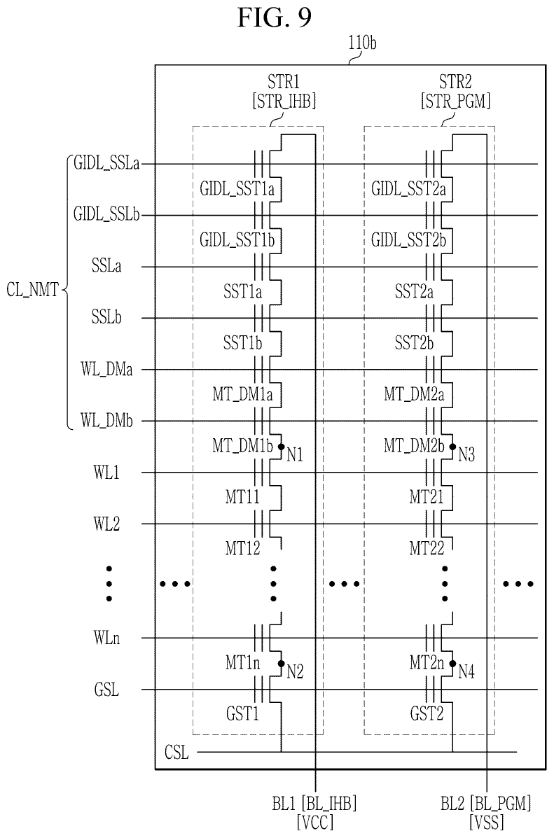

Hereinafter, for better understanding and ease of description, an implementation in which the row decoder 120 decreases the voltage level of the string selection line SSL to the ground voltage or less is representatively described. However, the scope of the present disclosure is not limited thereto, and the row decoder 120 may decrease the voltage of one of the various types of non-memory transistor control lines as well as the string selection line SSL to the ground voltage or less based on the boost retention logic BRL. An implementation in which the row decoder 120 decreases the voltage of one of various types of non-memory transistor control lines to the ground voltage or less will be described in more detail with reference to FIG. 9 to FIG. 11 below.

The control logic circuit 130 may receive the command CMD from the storage controller 10. The control logic circuit 130 may control overall operations of the nonvolatile memory device 100 based on the command CMD. For example, the control logic circuit 130 may control the operation of the row decoder 120, the page buffer circuit 140, and the input/output circuit 150 based on the command CMD.

The page buffer circuit 140 may temporarily store the user data DATA read from the memory cell array 110 through the plurality of bit lines BL or may temporarily store the data DATA to be stored in the memory cell array 110.

The page buffer circuit 140 may be connected to the memory cell array 110 through the plurality of bit lines BL. The page buffer circuit 140 may control the voltage levels of the plurality of bit lines BL based on the control of the control logic circuit 130. For example, the page buffer circuit 140 may change the voltage level of each of the plurality of bit lines BL to a ground voltage, a force voltage, or a power supply voltage.

In some implementations, the force voltage may be a voltage level higher than the ground voltage and lower than the power supply voltage.

The input/output circuit 150 may be connected to the page buffer circuit 140 through the plurality of data lines DL. The input/output circuit 150 may output the data DATA stored in the page buffer circuit 140 to the storage controller 10 or provide the data DATA provided from the storage controller 10 to the page buffer circuit 140.

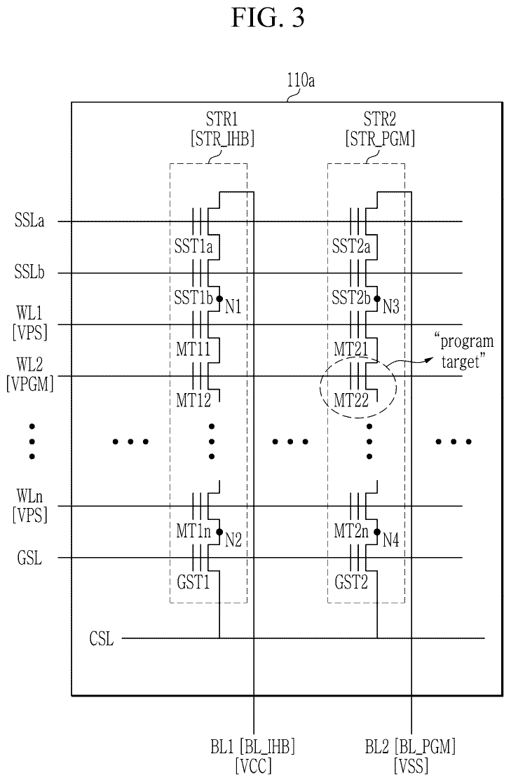

FIG. 3 illustrates an example detailed diagram of a part of configuration of a memory cell array of FIG. 2 implemented according to an implementation. Referring to FIG. 1 to FIG. 3, the memory cell array 110 may be implemented as a memory cell array 110a below.

The memory cell array 110a may include a first string STR1 and a second string STR2. Hereinafter, for better understanding and ease of description, configurations and functions of the first string STR1 and the second string STR2 among a plurality of strings STR included in the memory cell array 110a will be representatively described. However, the scope of the present disclosure is not limited thereto.

The first string STR1 may be connected to the first bit line BL1, and the second string STR2 may be connected to the second bit line BL2.

Each of the first string STR1 and the second string STR2 may include a plurality of string selection transistors SST, a plurality of memory transistors MT, and a ground selection transistor GST. For example, the first string STR1 may include first and second string selection transistors SST1a and SST1b, memory transistors MT11 to MT1n, and a ground selection transistor GST1. The second string STR2 may include first and second string selection transistors SST2a and SST2b, memory transistors MT21 to MT2n, and a ground selection transistor GST2.

The first string STR1 and the second string STR2 may be connected to first and second string selection lines SSLa and SSLb, first to n-th word lines WL1 to WLn, and a ground selection line GSL. For example, the first string selection line SSLa may be connected to gate terminals of the first string selection transistors SST1a and SST2a, the second string selection line SSLb may be connected to gate terminals of the second string selection transistors SST1b and SST2b, and the first to n-th word lines WL1 to WLn may be connected to gate terminals of the memory transistors MT11 to MT1n and the memory transistors MT21 to MT2n, respectively; and the ground selection line GSL may be connected to gate terminals of the ground selection transistors GST1 and GST2.

The first and second string selection transistors SST1a and SST1b, the memory transistors MT11 to MT1n, and the ground selection transistor GST1 may be connected in series. For example, the first and second string selection transistors SST1a and SST1b may be connected in series between the first bit line BL1 and the first node N1. The memory transistors MT11 to MT1n may be connected in series between the first node N1 and the second node N2. The ground selection transistor GST1 may be connected between the second node N2 and the common source line CSL.

The first and second string selection transistors SST2a and SST2b, the memory transistors MT21 to MT2n, and the ground selection transistor GST2 may be connected in series. For example, the first and second string selection transistors SST2a and SST2b may be connected in series between the second bit line BL2 and the third node N3. The memory transistors MT21 to MT2n may be connected in series between the third node N3 and the fourth node N4. The ground selection transistor GST2 may be connected between the fourth node N4 and the common source line CSL.

Each of a plurality of memory transistors MT may correspond to one memory cell. For example, each of the plurality of memory transistors MT may store data based on a threshold voltage.

Each of the plurality of string selection transistors SST may determine whether to connect the plurality of memory transistors MT to the bit line BL. For example, the first and second string selection transistors SST1a and SST1b may determine whether to connect the memory transistors MT11 to MT1n to the first bit line BL1 based on the voltage levels of the first and second string selection lines SSLa and SSLb, respectively.

Each of the plurality of ground selection transistors GST may determine whether to connect the plurality of memory transistors MT to the common source line CSL. For example, the first ground selection transistor GST1 may determine whether to connect the memory transistors MT11 to MT1n to the common source line CSL based on the voltage level of the ground selection line GSL.

The nonvolatile memory device 100 may perform a program operation on the second string STR2 based on the command CMD and the address ADDR. Hereinafter, the second string STR2 may also be referred to as a program string STR_PGM. The bit line BL connected to the second string STR2 (for example, the second bit line BL2) may also be referred to as a program bit line BL_PGM.

For a more detailed example, the nonvolatile memory device 100 may determine to program the memory transistor MT22 (hereinafter, referred to as a target memory transistor) included in the second string STR2. In this case, the row decoder 120 may apply a program voltage VPGM to a word line connected to the target memory transistor (for example, the second word line WL2; hereinafter referred to as a target word line WL_TG). The row decoder 120 may apply a pass voltage VPS to the remaining word lines (for example, the first word line WL1 and the third to n-th word lines WL3 to WLn; hereinafter, referred to as non-target word lines WL_NTG) other than the target word line WL_TG. The page buffer circuit 140 may provide a ground voltage VSS to the second bit line BL2. In this case, as the threshold voltage of the memory transistor MT22 changes, data stored in the memory transistor MT22 may change. However, the scope of the present disclosure is not limited thereto, and the page buffer circuit 140 may provide a force voltage that is greater than the ground voltage VSS and less than the power supply voltage VCC to the second bit line BL2.

In some implementations, the program voltage VPGM may be a voltage high enough to change the threshold voltage of the memory transistor MT.

In some implementations, the pass voltage VPS may be a voltage high enough to turn on the memory transistor MT but low enough not to change the threshold voltage of the memory transistor MT.

While performing the program operation on the second string STR2, the nonvolatile memory device 100 may perform a program inhibit operation on the first string STR1. Hereinafter, the first string STR1 may be referred to as an ‘inhibit string STR_IHB’. The bit line BL (for example, the first bit line BL1) connected to the first string STR1 may be referred to as an inhibit bit line BL_IHB.

The nonvolatile memory device 100 may perform a program inhibit operation on the inhibit string STR_IHB based on a self-boosting scheme while performing a program operation on the program string STR_PGM.

For a more detailed example, the page buffer circuit 140 may provide the power supply voltage VCC to the inhibit bit line BL_IHB. In this case, the channel voltages of the memory transistors MT11 to MT1n may be boosted to a voltage level similar to that of the program voltage VPGM, and accordingly, even if the program voltage VPGM is provided to the gate terminal of the memory transistor MT12, the memory transistor MT12 may not be programmed.

In some implementations, while the program operation on the second string STR2 is performed, the first and second string selection transistors SST1a and SST1b and the ground selection transistor GST1 may be turned off.

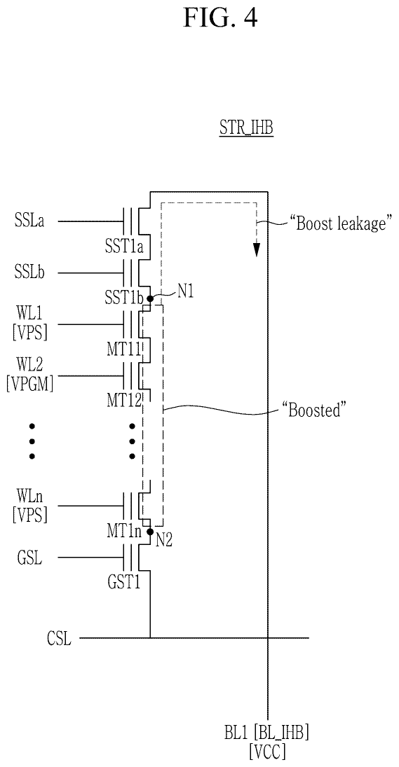

That is, the nonvolatile memory device 100 may perform a program inhibit operation on the inhibit string STR_IHB by boosting the channel voltages of the memory transistors MT included in the inhibit string STR_IHB. However, when a boost leakage phenomenon occurs for the channel voltage of the memory transistors MT, the program inhibit operation for the inhibit string STR_IHB may fail. The self-boosting scheme and the boost leakage phenomenon will be described in more detail with reference to FIG. 4.

FIG. 4 is an example diagram illustrating a self-boosting scheme applied to an inhibit string of FIG. 3 and a boost leakage phenomenon in more detail. Referring to FIG. 1 to FIG. 4, the inhibit string STR_IHB may include first and second string selection transistors SST1a and SST1b, memory transistors MT11 to MT1n, and a ground selection transistor GST1.

While the program inhibit operation for the inhibit string STR_IHB is performed, each of the memory transistors MT11 to MT1n may be turned on based on the voltage level of the corresponding word line WL. For example, a channel may be formed between a drain terminal and a source terminal of each of the memory transistors MT11 to MT1n based on the voltage level of the first to n-th word lines WL1 to WLn.

While the program inhibit operation for the inhibit string STR_IHB is performed, at least one of the first and second string selection transistors SST1a and SST1b may be turned off. For example, as the power supply voltage VCC is provided to the first bit line BL1, at least one of the first and second string selection transistors SST1a and SST1b may be turned off.

While the program inhibit operation for the inhibit string STR_IHB is performed, the ground selection transistor GST1 may be turned off. For example, the row decoder 120 may set the voltage level of the ground selection line GSL to the ground voltage VSS.

As at least one of the first and second string selection transistors SST1a and SST1b and the ground selection transistor GST1 are turned off, the channels of the memory transistors MT11 to MT1n may be floated. In this case, the voltage level of the channels of the memory transistors MT11 to MT1n may be determined based on the voltage level provided to the gate terminals of the memory transistors MT11 to MT1n. For example, the voltage level of the channel of the memory transistors MT11 to MT1n may be boosted to a level similar to the program voltage VPGM by capacitive coupling between the channel and the gate terminal of the memory transistors MT11 to MT1n. In this case, the memory transistors MT11 to MT1n may not be programmed.

However, a boost leakage phenomenon may occur even though at least one of the first and second string selection transistors SST1a and SST1b is turned off. For example, charges may leak from the channels of the memory transistors MT11 to MT1n to the first bit line BL1 through the first and second string selection transistors SST1a and SST1b. In this case, the channel voltage of the memory transistor MT12 connected to the target word line WL_TG may decrease, and accordingly, the difference between the gate voltage and channel voltage of the memory transistor MT12 may increase. Accordingly, the threshold voltage of the memory transistor MT12 may increase, and thus the reliability of data stored in the nonvolatile memory device 100 may decrease.

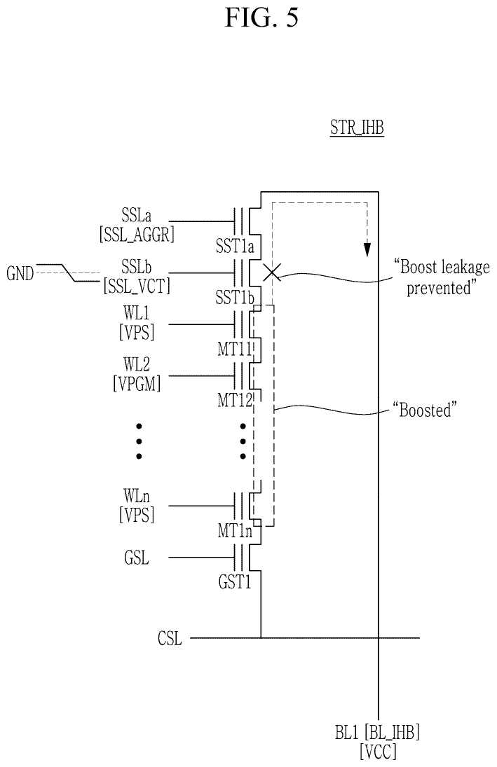

FIG. 5 illustrates an example of a program inhibit based on a boost retention logic in more detail. Referring to FIG. 1 to FIG. 5, the nonvolatile memory device 100 may perform a program inhibit operation based on the boost retention logic BRL. For example, the row decoder 120 may decrease the voltage level of one of the first and second string selection lines SSLa and SSLb to be lower than the ground voltage GND (for example, to a negative voltage) based on the boost retention logic BRL. In this case, charge leakage from the channels of the memory transistors MT11 to MT1n through the first and second string selection transistors SST1a and SST1b may be minimized.

That is, according to an implementation of the present disclosure, since charge leakage from the channel of the memory transistors MT11 to MT1n may be minimized, the voltage level of the channel of the memory transistors MT11 to MT1n may be maintained at a level similar to the program voltage VPGM. In this case, even if the program voltage VPGM is provided to the target word line WL_TG (for example, the second word line WL2), the threshold voltage of the memory transistor MT (for example, the memory transistor MT12) connected to the target word line WL_TG may not change. Accordingly, since data stored in the inhibit string STR_IHB may not be damaged, reliability of data stored in the nonvolatile memory device 100 may be guaranteed.

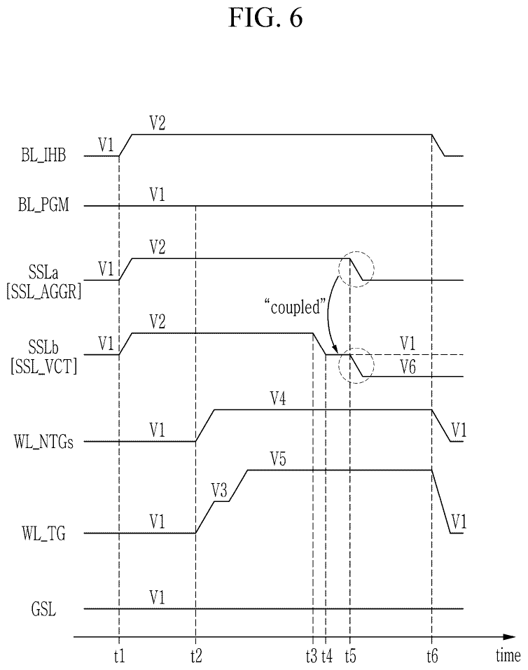

In some implementations, the row decoder 120 may sequentially control the voltage levels of the first and second string selection lines SSLa and SSLb to decrease the voltage level of one of the first and second string selection lines SSLa and SSLb to be lower than the ground voltage GND. In this case, the row decoder 120 may decrease the voltage level of one of the first and second string selection lines SSLa and SSLb to be lower than the ground voltage even without having a dedicated circuit for generating a negative voltage, so that the nonvolatile memory device 100 may be implemented in a smaller area, and the production cost of the nonvolatile memory device 100 may be reduced. A specific method in which the row decoder 120 sequentially controls the voltage levels of the first and second string selection lines SSLa and SSLb will be described in more detail with reference to FIG. 6.

FIG. 6 illustrates a detailed timing diagram of an example operation of a nonvolatile memory device. The horizontal axis of FIG. 6 represents time, and the vertical axis thereof represents voltage levels.

Referring to FIG. 1 to FIG. 6, the nonvolatile memory device 100 may set up bit lines BL and string selection lines SSL between a first time point t1 and a second time point t2. For example, at the first time point t1, the page buffer circuit 140 may increase the voltage level of the inhibit bit line BL_IHB from the first voltage V1 to the second voltage V2, and maintain the voltage level of the program bit line BL_PGM at the first voltage V1. At the first time point t1, the row decoder 120 may increase the voltage level of the first and second string selection lines SSLa and SSLb to the second voltage V2.

In some implementations, the first voltage V1 may be the ground voltage VSS, and the second voltage V2 may be the power supply voltage VCC.

For better understanding and ease of description, FIG. 6 illustrates an implementation in which the inhibit bit line BL_IHB and the string selection lines SSL rise to the same voltage level at the first time t1, but the scope of the present disclosure is not limited thereto. For example, the page buffer circuit 140 may increase the voltage level of the inhibit bit line BL_IHB to a power supply voltage of the page buffer circuit 140, and the row decoder 120 may increase the voltage level of the first and second string selection lines SSLa and SSLb to a power supply voltage of the row decoder 120. In this case, the power supply voltage of the page buffer circuit 140 may be different from the power supply voltage of the row decoder 120.

Between the second time point t2 and the sixth time point t6, the nonvolatile memory device 100 may perform a program operation on the program string STR_PGM. For example, at the second time point t2, the row decoder 120 may increase the voltage level of the target word line WL_TG to the fifth voltage V5 through the third voltage V3, and may increase the voltage level of the non-target word lines WL_NTG to the fourth voltage V4. In this case, the threshold voltage of the target memory transistor included in the program string STR_PGM may increase based on the fifth voltage V5, and the channel voltage of the memory transistors MT included in the inhibit string STR_IHB may increase.

In some implementations, the fourth voltage V4 may be the pass voltage VPS, and the fifth voltage V5 may be the program voltage VPGM.

In some implementations, the third voltage V3 may be a voltage higher than the first voltage V1 and lower than the fifth voltage V5. For example, the third voltage V3 may have the same voltage level as the fourth voltage V4. However, the scope of the present disclosure is not limited thereto.

Between the third time point t3 and the sixth time point t6, the row decoder 120 may sequentially control the first and second string selection lines SSLa and SSLb based on the boost retention logic BRL to decrease the voltage level of one of the first and second string selection lines SSLa and SSLb to the first voltage V1 or less. Hereinafter, an implementation in which the row decoder 120 decreases the voltage level of the second string selection line SSLb to less than the first voltage V1 will be described.

First, at a third time point t3, the row decoder 120 may decrease the voltage level of the second string selection line SSLb to the first voltage V1. However, the scope of the present disclosure is not limited thereto, and the row decoder 120 may decrease the voltage of the second string selection line SSLb to any voltage level lower than the second voltage V2.

In some implementations, after the fourth time point t4 at which the voltage level of the second string selection line SSLb is completed to be decreased to the first voltage V1, the row decoder 120 may float the second string selection line SSLb. In this case, the second string selection line SSLb may be floated in a state in which the voltage level is maintained at the first voltage V1.

Thereafter, at the fifth time point t5, the row decoder 120 may decrease the voltage level of the first string selection line SSLa to the first voltage V1. However, the scope of the present disclosure is not limited thereto, and the row decoder 120 may decrease the voltage of the first string selection line SSLa to any voltage level lower than the second voltage V2.

As the voltage level of the first string selection line SSLa decreases, the voltage level of the second string selection line SSLb may decrease to the sixth voltage V6 lower than the first voltage V1 due to coupling between the first string selection line SSLa and the second string selection line SSLb. In this case, since the amount of charge leaking through the string selection transistor SST operating based on the sixth voltage V6 may be minimized, the boost leakage phenomenon may be minimized. Therefore, according to an implementation of the present disclosure, since the channel voltage of the memory transistors MT included in the inhibit string STR_IHB may be maintained, the reliability of data stored in the inhibit string STR_IHB may be improved.

According to an implementation of the present disclosure, the voltage level change of the second string selection line SSLb may be caused by the voltage level change of the first string selection line SSLa. In this regard, the first string selection line SSLa may be referred to as an aggressor line or aggressor string selection line SSL_AGGR, and the second string selection line SSLb may be referred to as a victim line or a victim string selection line SSL_VCT.

In some implementations, between the second time point t2 and the third time point t3, the page buffer circuit 140 may increase the voltage level of the program bit line BL_PGM from the first voltage V1. For example, the page buffer circuit 140 may increase the voltage level of the program bit line BL_PGM to a forcing voltage between the first voltage V1 and the second voltage V2. In this case, a speed of which the threshold voltage of the target memory transistor rises may be controlled based on the forcing voltage.

After the sixth time point t6 when the program for the program string STR_PGM is completed, the nonvolatile memory device 100 may recover the bit lines BL and the string selection lines SSL. For example, after the sixth time point t6, the page buffer circuit 140 may decrease the voltage level of the inhibit bit line BL_IHB to the first voltage V1; the row decoder 120 may decrease the voltage level of the plurality of word lines WL to the first voltage V1.

In some implementations, between the first time point t1 and the sixth time point t6, the row decoder 120 may maintain the ground selection line GSL at the first voltage V1.

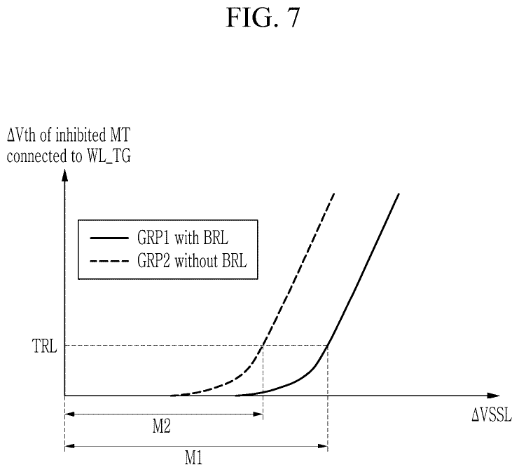

FIG. 7 illustrates example program inhibit performance. Hereinafter, the program inhibit performance when the row decoder 120 operates based on the boost retention logic BRL and when the row decoder 120 operates without the boost retention logic BRL will be described with reference to FIG. 1 to FIG. 7.

The horizontal axis of FIG. 7 may indicate a string selection line voltage level error (ΔVSSL). More specifically, the string selection line voltage level error (ΔVSSL) may represent a difference between a voltage level actually provided to the string selection line SSL and a voltage level of the intended string selection line SSL. For example, when the voltage level to be provided to the string selection line SSL is 3.3 V and the voltage level of the actual string selection line SSL is 3.5 V, the string selection line voltage level error (ΔVSSL) may be 0.2 V.

In some implementations, the string selection line voltage level error (ΔVSSL) may occur due to various factors such as a coupling phenomenon between the string selection line SSL and other components, a process deviation of the nonvolatile memory device 100, and the like.

The vertical axis of FIG. 7 may represent the threshold voltage variation of the inhibited memory transistor MT connected to the target word line WL_TG. That is, the vertical axis of FIG. 7 may represent the magnitude of increase in the threshold voltage of the memory transistor MT connected to the target word line WL_TG among the memory transistors MT included in the inhibit string STR_IHB after the program operation for the program string STR_PGM is completed.

The relationship between the string selection line voltage level error (ΔVSSL) and the threshold voltage variation of the inhibit memory transistor MT when the row decoder 120 operates based on the boost retention logic BRL is illustrated in a first graph GRP1 (solid line). That is, the first graph GRP1 represents the program inhibit performance when the row decoder 120 decrease a voltage level of one string selection line SSL below the ground voltage in the manner described above with reference to FIG. 6.

The relationship between the string selection line voltage level error (ΔVSSL) and the threshold voltage variation of the inhibit memory transistor MT when the row decoder 120 operates without being based on the boost retention logic BRL is illustrated in a second graph GRP2 (dotted line). That is, the second graph GRP2 represents a program inhibit performance when the row decoder 120 maintains both the voltage levels of the first and second string selection lines SSLa and SSLb at the first voltage V1 or the second voltage V2 (more specifically, when the row decoder 120 simultaneously decreases the voltage level of the first and second string selection lines SSLa and SSLb to the first voltage V1 at the third time point t3, or when the row decoder 120 maintains the voltage level of the first and second string selection lines SSLa and SSLb at the second voltage V2 at the first to sixth time points t1 to t6), unlike described above with reference to FIG. 6.

Referring to the first graph GRP1, the magnitude of the string selection line voltage level error (ΔVSSL) that causes the threshold voltage of the inhibited memory transistor MT to increase by the tolerance level TRL may be the first margin M1.

Referring to the second graph GRP2, the magnitude of the string selection line voltage level error (ΔVSSL) that causes the threshold voltage of the inhibited memory transistor MT to increase by the tolerance level TRL may be the second margin M2.

In some implementations, the tolerance level TRL may be a maximum voltage for preventing data stored in the inhibited memory transistor MT from being misread due to a change in the threshold voltage of the inhibited memory transistor MT. However, the scope of the present disclosure is not limited thereto, and the tolerance level TRL may be any voltage level.

The first margin M1 may be greater than the second margin M2. In this case, even if the voltage level of the string selection line SSL is higher than intended, the reliability of the data stored in the inhibited memory transistor MT may be improved. That is, when the row decoder 120 operates based on the boost retention logic BRL, the boost leakage phenomenon may be minimized, and even if an error occurs in the voltage level of the string selection line SSL, the possibility of the data stored in the inhibited memory transistor MT being changed may be minimized.

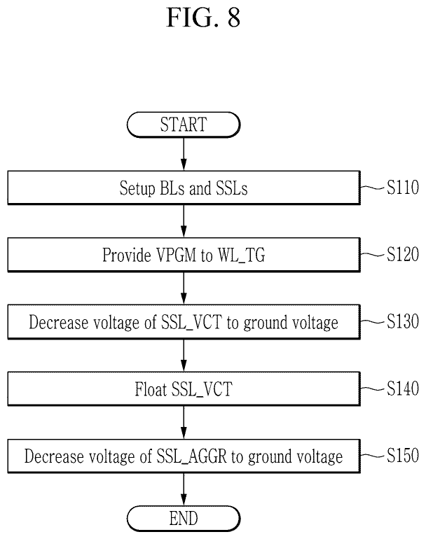

FIG. 8 illustrates a flowchart of an example operation of the nonvolatile memory device of FIG. 2. Referring to FIG. 1 to FIG. 8, in operation S110, the nonvolatile memory device 100 may setup the bit lines BL and the string selection lines SSL. For example, the page buffer circuit 140 may setup the inhibit bit line BL_IHB to the second voltage V2 and the program bit line BL_PGM to the first voltage V1. The row decoder 120 may setup the victim string selection line SSL_VCT and the aggressor string selection line SSL_AGGR to the second voltage V2.

In operation S120, the nonvolatile memory device 100 may provide the program voltage VPGM to the target word line WL_TG. For example, the row decoder 120 may provide the program voltage VPGM to the target word line WL_TG and the pass voltage VPS to the non-target word line WL_NTG.

In operation S130, the nonvolatile memory device 100 may decrease the voltage of the victim string selection line SSL_VCT to the ground voltage. For example, the row decoder 120 may decrease the voltage of the second string selection line SSLb from the second voltage V2 to the first voltage V1. Meanwhile, the row decoder 120 may maintain the voltage of the aggressor string selection line SSL_AGGR (for example, the first string selection line SSLa) at the second voltage V2.

In operation S140, the nonvolatile memory device 100 may float the victim string selection line SSL_VCT. For example, the row decoder 120 may float the victim string selection line SSL_VCT after the voltage of the victim string selection line SSL_VCT is decreased to the ground voltage (for example, after a predetermined time has elapsed after providing the first voltage V1 to the second string selection line SSLb).

In operation S150, the nonvolatile memory device 100 may decrease the voltage of the aggressor string selection line SSL_AGGR to the ground voltage VSS. For example, the row decoder 120 may decrease the voltage of the first string selection line SSLa to the ground voltage VSS. In this case, the voltage level of the victim string selection line SSL_VCT may be decreased below the ground voltage VSS by the coupling between the aggressor string selection line SSL_AGGR and the victim string selection line SSL_VCT.

FIG. 9 illustrates an example detailed diagram of a part of configuration of a memory cell array of FIG. 2. Referring to FIG. 1, FIG. 2, and FIG. 9, the memory cell array 110 of FIG. 2 may be implemented as a memory cell array 110b. Hereinafter, a difference between the memory cell array 110a and the memory cell array 110b will be mainly described. For a more concise description, detailed descriptions of components of the memory cell array 110b, which are similar to those of the memory cell array 110a, will be omitted.

The memory cell array 110 may include a first string STR1 and a second string STR2. The first string STR1 may be connected to the first bit line BL1, and the second string STR2 may be connected to the second bit line BL2.

Memory transistors MT11 to MT1n may be connected between the first node N1 and the second node N2. A ground selection transistor GST1 may be connected between the second node N2 and the common source line CSL. Memory transistors MT21 to MT2n may be connected between the third node N3 and the fourth node N4. A ground selection transistor GST2 may be connected between the fourth node N4 and the common source line CSL. The functions and operations of the plurality of memory transistors MT and the ground selection transistor GST have been described above with reference to FIG. 3, so a detailed description thereof will be omitted.

A plurality of non-memory transistors (hereinafter referred to as NMT) may be connected in series between the first bit line BL1 and the first node N1 and between the second bit line BL2 and the third node N3. For example, first and second gate-induced drain leakage (GIDL) string selection transistors GIDL_SST1a and GIDL_SST1b, first and second string selection transistors SST1a and SST1b, and first and second dummy memory transistors MT_DM1a and MT_DM1b may be connected in series between the first bit line BL1 and the first node N1. First and second GIDL string selection transistors GIDL_SST2a and GIDL_SST2b, first and second string selection transistors SST2a and SST2b, and first and second dummy memory transistors MT_DM2a and MT_DM2b may be connected in series between the second bit line BL2 and the third node N3.

Non-memory transistors NMT may refer to transistors among the transistors included in the memory cell array 110 that is not used to store data provided from outside the storage device 1. For example, the GIDL string selection transistor GIDL_SST, the string selection transistor SST, and the dummy memory transistor MT_DM may also be referred to as non-memory transistors NMT.

For a more concise description, FIG. 9 illustrates an implementation in which each string STR includes two GIDL string selection transistors GIDL_SST, two string selection transistors SST, and two dummy memory transistors MT_DM, but the scope of the present disclosure is not limited thereto. For example, each string STR may include any number of GIDL string selection transistors GIDL_SST, one or more string selection transistors SST, and any number of dummy memory transistors MT_DM. In addition, other transistors not shown in FIG. 9 may be further included in each string STR.

In addition, the scope of the present disclosure is not limited to the order in which the GIDL string selection transistor GIDL_SST, the string selection transistor SST, and the dummy memory transistor MT_DM are located in each string. For example, the GIDL string selection transistor GIDL_SST may be located closer to the bit line than the string selection transistor SST.

In some implementations, the GIDL string selection transistors GIDL_SST may refer to transistors configured to supply a charge to a corresponding string STR while an erase operation is performed on the memory cell array 110.

In some implementations, the dummy memory transistors MT_DM may refer to transistors that are implemented in the same manner as the memory transistor MT but are configured not to store data to ensure the reliability of the nonvolatile memory device 100. The dummy memory transistor MT_DM may be located at terminals of a plurality of memory transistors MT. For example, the dummy memory transistors MT_DM may be connected between the first node N1 and the string selection transistor SST. However, the scope of the present disclosure is not limited thereto, and the dummy memory transistors MT_DM may be connected between the second node N2 and the ground selection transistor GST1.

In some implementations, each string STR may be divided into an upper peripheral area, a cell area, and a lower peripheral area. In this case, the upper peripheral area may include a plurality of non-memory transistors NMT connected between the bit line BL and the plurality of memory transistors MT. For example, the upper peripheral area may include the first and second GIDL string selection transistors GIDL_SST1a and GIDL_SST1b, the first and second string selection transistors SST1a and SST1b, and the first and second dummy memory transistors MT_DM1a and MT_DM1b. The cell area may include a plurality of memory transistors MT. For example, the cell area may include the memory transistors MT11 to MT1n. The lower peripheral area may include a plurality of non-memory transistors NMT connected between the common source line CSL and the plurality of memory transistors MT. For example, the lower peripheral area may include a ground selection transistor GST1.

The first string STR1 and the second string STR2 may be connected to a plurality of non-memory transistor control lines CL_NMT. For example, the first string STR1 and the second string STR2 may be connected to the first and second GIDL string selection lines GIDL_SSLa and GIDL_SSLb, the first and second string selection lines SSLa and SSLb, and the first and second dummy word lines WL_DMa and WL_DMb.

More specifically, the gate terminals of the first GIDL string selection transistors GIDL_SST1a and GIDL_SST2a may be connected to the first GIDL string selection line GIDL_SSLa; the gate terminals of the second GIDL string selection transistors GIDL_SST1b and GIDL_SST2b may be connected to the second GIDL string selection line GIDL_SSLb; the first GIDL string selection line GIDL_SSLa may be connected to gate terminals of the first GIDL string selection transistors GIDL_SST1a and GIDL_SST2a; the second GIDL string selection line GIDL_SSLb may be connected to gate terminals of the second GIDL string selection transistors GIDL_SST1b and GIDL_SST2b; the first string selection line SSLa may be connected to the gate terminals of the first string selection transistors SST1a and SST2a; the second string selection line SSLb may be connected to the gate terminals of the second string selection transistors SST1b and SST2b; the first dummy word line WL_DMa may be connected to the gate terminals of the first dummy memory transistors MT_DM1a and MT_DM2a; and the second dummy word line WL_DMb may be connected to the gate terminals of the second dummy memory transistors MT_DM1b and MT_DM2b.

The non-memory transistor control line CL_NMTs may refer to control lines connected between the non-memory transistor NMT and the row decoder 120. For example, the GIDL string selection line GIDL_SSL, the string selection line SSL, and the dummy word line WL_DM may also be referred to as a non-memory transistor control line CL_NMT.

The nonvolatile memory device 100 may perform a program operation for the second string STR2 and a program inhibit operation for the first string STR1 based on the command CMD and the address ADDR. In this case, the first string STR1 may be referred to as an inhibit string STR_IHB, and the second string STR2 may be referred to as a program string STR_PGM. The first bit line BL1 may be referred to as an inhibit bit line BL_IHB, and the second bit line BL2 may be referred to as a program bit line BL_PGM.

The nonvolatile memory device 100 may decrease a voltage level of one of the plurality of non-memory transistor control lines CL_NMT connected to the plurality of non-memory transistors NMT between the first node N1 and the first bit line BL1 to the ground voltage VSS or less in a manner similar to that described above with reference to FIG. 1 to FIG. 8. For example, the nonvolatile memory device 100 may execute the boost retention logic BRL by selecting two non-memory transistor control lines CL_NMT from the plurality of non-memory transistor control lines CL_NMT as the aggressor string selection line SSL_AGGR and the victim stream selection line SSL_AGGR described above with reference to FIG. 1 to FIG. 8.

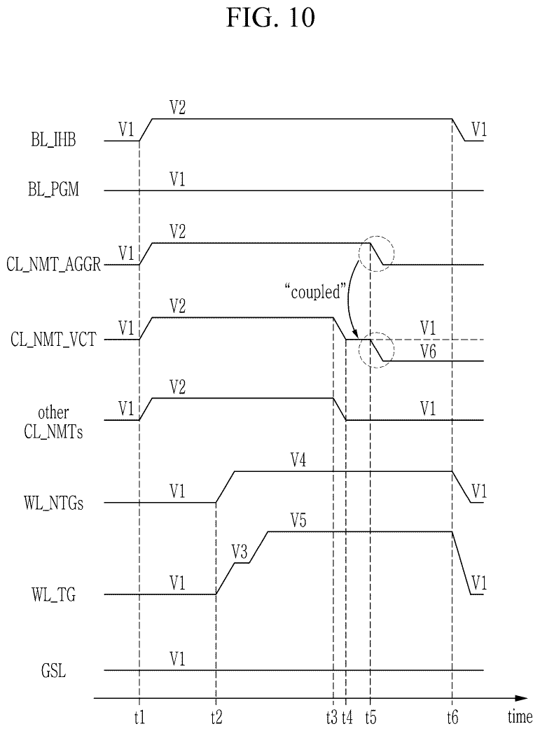

For a more detailed example, the nonvolatile memory device 100 may select two of the plurality of non-memory transistor control lines CL_NMT respectively connected to the plurality of non-memory transistors NMT included in the upper peripheral area. The nonvolatile memory device 100 may determine two non-memory transistor control lines CL_NMT as the aggressor non-memory transistor control line CL_NMT_AGGR and the victim non-memory transistor control line CL_NMT_VCT, respectively. In this case, the row decoder 120 may sequentially control the aggressor non-memory transistor control line CL_NMT_AGGR and the victim non-memory transistor control line CL_NMT_VCT based on the boost retention logic BRL to decrease the voltage level of the victim non-memory transistor control line CL_NMT_VCT to be lower than the ground voltage VSS. Accordingly, according to an implementation of the present disclosure, the boost leakage phenomenon from the channel of the memory transistors MT11 to MT1n may be minimized. A method in which the row decoder 120 controls the aggressor non-memory transistor control line CL_NMT_AGGR and the victim non-memory transistor control line CL_NMT_VCT will be described in more detail with reference to FIG. 10 below.

That is, hereinafter, an implementation of preventing the boost leakage phenomenon from the channel of the memory transistor MT to the bit line BL will be described, similarly to that described above with reference to FIG. 1 to FIG. 8. Accordingly, unless otherwise described, hereinafter, the non-memory transistor NMT will refer to the non-memory transistor NMT included in the upper peripheral area, and the non-memory transistor control line CL_NMT will refer to the non-memory transistor NMT included in the upper peripheral area. However, the scope of the present disclosure is not limited thereto.

In some implementations, the nonvolatile memory device 100 may determine two adjacent non-memory transistor control lines among the plurality of non-memory transistor control lines CL_NMT respectively connected to the plurality of non-memory transistors NMT included in the upper peripheral area as an aggressor non-memory transistor control line CL_NMT_AGGR and a victim non-memory transistor control line CL_NMT_VCT, respectively. That is, the aggressor non-memory transistor control line CL_NMT_AGGR and the victim non-memory transistor control line CL_NMT_VCT may be disposed adjacent to each other. Accordingly, the non-memory transistor connected to the aggressor non-memory transistor control line CL_NMT_AGGR and the non-memory transistor connected to the victim non-memory transistor control line CL_NMT_VCT may be directly connected to each other. For example, the drain terminal of the non-memory transistor connected to the aggressor non-memory transistor control line CL_NMT_AGGR may be directly connected to the source terminal of the non-memory transistor connected to the victim non-memory transistor control line CL_NMT_VCT. Alternatively, the source terminal of the non-memory transistor connected to the aggressor non-memory transistor control line CL_NMT_AGGR may be directly connected to the drain terminal of the non-memory transistor connected to the victim non-memory transistor control line CL_NMT_VCT.

FIG. 10 illustrates an example detailed timing diagram of an operation of a nonvolatile memory device. The horizontal axis of FIG. 10 represents time, and the vertical axis thereof represents voltage levels.

Referring to FIG. 1, FIG. 2, FIG. 9, and FIG. 10, the nonvolatile memory device 100 may control a plurality of bit lines BL, a plurality of word lines WL, and a ground selection line GSL in a method similar to that described above with reference to FIG. 6. Hereinafter, a method in which the nonvolatile memory device 100 controls the non-memory transistor control lines CL_NMT connected to the non-memory transistors NMT included in the upper peripheral area will be mainly described.

The nonvolatile memory device 100 may set up a plurality of non-memory transistor control lines CL_NMT between the first time point t1 and the second time point t2. For example, the row decoder 120 may increase the voltage level of the non-memory transistor control lines CL_NMT to the second voltage V2 at the first time point t1.

Between the third time point t3 and the sixth time point t6, the row decoder 120 may sequentially control the aggressor non-memory transistor control line CL_NMT_AGGR and the victim non-memory transistor control line CL_NMT_VCT based on the boost retention logic BRL to decrease the voltage level of the victim non-memory transistor control line CL_NMT_VCT to be the first voltage V1 or less.

First, at the third time t3, the row decoder 120 may decrease the voltage level of the victim non-memory transistor control line CL_NMT_VCT to the first voltage V1. However, the scope of the present disclosure is not limited thereto, and the row decoder 120 may decrease the voltage of the victim non-memory transistor control line CL_NMT_VCT to any voltage level lower than the second voltage V2.

After the fourth time t4 when the voltage level of the victim non-memory transistor control line CL_NMT_VCT is decreased to the first voltage V1, the row decoder 120 may float the victim non-memory transistor control line CL_NMT_VCT. In this case, the victim non-memory transistor control line CL_NMT_VCT may be floated in a state in which the voltage level is maintained at the first voltage V1.

Thereafter, at the fifth time point t5, the row decoder 120 may decrease the voltage level of the aggressor non-memory transistor control line CL_NMT_AGGR to the first voltage V1. However, the scope of the present disclosure is not limited thereto, and the row decoder 120 may also decrease the voltage of the aggressor non-memory transistor control line CL_NMT_AGGR to any voltage level lower than the second voltage V2.

As the voltage level of the aggressor non-memory transistor control line CL_NMT_AGGR decreases, the voltage level of the victim non-memory transistor control line CL_NMT_VCT may decrease to the sixth voltage V6 lower than the first voltage V1 due to the coupling between the aggressor non-memory transistor control line CL_NMT_AGGR and the victim non-memory transistor control line CL_NMT_VCT. Accordingly, according to an implementation of the present disclosure, the reliability of data stored in the inhibit string STR_IHB may be improved. The principle of improving the reliability of data stored in the inhibit string STR_IHB is similar to that described above with reference to FIG. 3 to FIG. 7, so a detailed description thereof will be omitted.

In some implementations, when the aggressor non-memory transistor control line CL_NMT_AGGR and the victim non-memory transistor control line CL_NMT_VCT are determined as a pair of adjacent non-memory transistor control lines, the aggressor non-memory transistor control line CL_NMT_AGGR and the victim non-memory transistor control line CL_NMT_VCT may be more strongly coupled. In this case, the voltage level of the victim non-memory transistor control line CL_NMT_VCT may change relatively significantly based on the voltage level variation of the aggressor non-memory transistor control line CL_NMT_AGGR. In this case, the voltage level of the victim non-memory transistor control line CL_NMT_VCT may be significantly decreased below the ground voltage VSS, and thus the boost leakage phenomenon may be more strongly prevented.

In some implementations, the row decoder 120 may decrease the voltage level of the remaining non-memory transistor control lines CL_NMT excluding the aggressor non-memory transistor control line CL_NMT_AGGR and the victim non-memory transistor control line CL_NMT_VCT among the non-memory transistor control lines CL_NMT connected to the non-memory transistors included in the upper peripheral area to the first voltage V1 at the third time point t3. However, the scope of the present disclosure is not limited to the specific time point at which the voltage level of the remaining non-memory transistor control lines CL_NMT described above is decreased. For example, the row decoder 120 may decrease the voltage level of the remaining non-memory transistor control line CL_NMT to the first voltage V1 at the fourth time point t4.

In some implementations, the row decoder 120 may control the dummy word line WL_DM that is not determined as the aggressor non-memory transistor control line CL_NMT_AGGR or the victim non-memory transistor control line CL_NMT_VCT in the same manner as the non-target word lines WL_NTG. For example, the row decoder 120 may provide the fourth voltage V4 to the dummy word line WL_DM that is not determined as the aggressor non-memory transistor control line CL_NMT_AGGR or the victim non-memory transistor control line CL_NMT_VCT at the second time point t2.

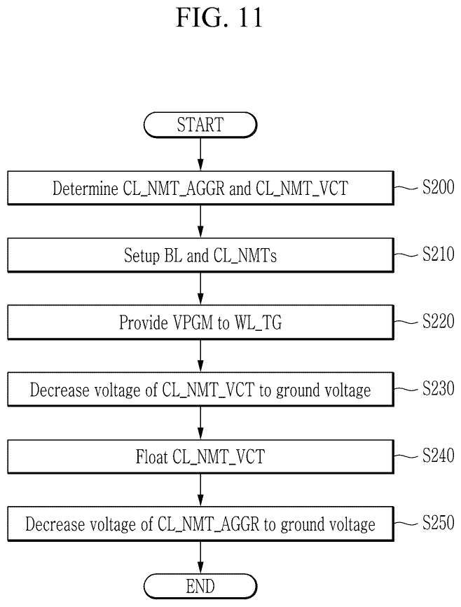

FIG. 11 illustrates a flowchart of an example operation of the nonvolatile memory device of FIG. 10. Referring to FIG. 1, FIG. 2, FIG. 9, and FIG. 11, in operation S200, the nonvolatile memory device 100 may determine the aggressor non-memory transistor control line CL_NMT_AGGR and the victim non-memory transistor control line CL_NMT_VCT. For example, the nonvolatile memory device 100 may determine two of the plurality of non-memory transistor control lines CL_NMT respectively connected to the plurality of non-memory transistors NMT disposed in the upper peripheral area as the aggressor non-memory transistor control line CL_NMT_AGGR and the victim non-memory transistor control line CL_NMT_VCT, respectively.

In operation S210, the nonvolatile memory device 100 may set up the bit lines BL and the plurality of non-memory transistor control lines CL_NMT. For example, the page buffer circuit 140 may set the inhibit bit line BL_IHB to the second voltage V2 and the program bit line BL_PGM to the first voltage V1. The row decoder 120 may set the plurality of non-memory transistor control lines CL_NMT to the second voltage V2.

In operation S220, the nonvolatile memory device 100 may provide the program voltage VPGM to the target word line WL_TG. For example, the row decoder 120 may provide the program voltage VPGM to the target word line WL_TG and the pass voltage VPS to the non-target word line WL_NTG.

In operation S230, the nonvolatile memory device 100 may decrease the voltage of the victim non-memory transistor control line CL_NMT_VCT to the ground voltage. For example, the row decoder 120 may decrease the voltage of the victim non-memory transistor control line CL_NMT_VCT from the second voltage V2 to the first voltage V1. Meanwhile, the row decoder 120 may maintain the voltage of the aggressor non-memory transistor control line CL_NMT_AGGR at the second voltage V2.

In operation S240, the nonvolatile memory device 100 may float the victim non-memory transistor control line CL_NMT_VCT. For example, the row decoder 120 may float the victim non-memory transistor control line CL_NMT_VCT after the voltage of the victim non-memory transistor control line CL_NMT_VCT is decreased to the ground voltage (for a more detailed example, after a predetermined time has elapsed after providing the first voltage V1 to the victim non-memory transistor control line CL_NMT_VCT).

In operation S250, the nonvolatile memory device 100 may decrease the voltage of the aggressor non-memory transistor control line CL_NMT_AGGR to the ground voltage VSS. In this case, the voltage level of the victim non-memory transistor control line CL_NMT_VCT may be decreased below the ground voltage VSS due to the coupling between the aggressor non-memory transistor control line CL_NMT_AGGR and the victim non-memory transistor control line CL_NMT_VCT.

That is, according to an implementation of the present disclosure, by controlling two of the plurality of non-memory transistors NMT included between the memory transistors MT and the inhibit bit line BL_IHB in the inhibit string STR_IHB (more specifically, controlling the non-memory transistor control lines CL_NMT respectively connected to them), the boost leakage phenomenon from the channel of the memory transistors MT in the inhibit string STR_IHB may be minimized. In this case, the program inhibit performance for the inhibit string STR_IHB may be improved. Accordingly, according to an implementation of the present disclosure, since data stored in the inhibit string STR_IHB may not be damaged, reliability of data stored in the nonvolatile memory device 100 may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above-described contents are implementations for implementing the present disclosure. The present disclosure will include not only the above-described implementations, but also implementations that may be simply design-changed or easily changed. In addition, the present disclosure will also include techniques that may be easily modified and implemented by using the implementations. While the present disclosure has been described with reference to implementations thereof, it will be apparent to those of ordinary skill in the art that various changes and modifications may be made thereto without departing from the spirit and scope of the disclosure as set forth in the following claims.

What is claimed is:

1. A nonvolatile memory device comprising:
a first string including a plurality of memory transistors, a first non-memory transistor, and a second non-memory transistor; and
a row decoder configured to
control a plurality of word lines, a first non-memory transistor control line, and a second non-memory transistor control line, the plurality of word lines being connected to the plurality of memory transistors respectively, the first non-memory transistor control line and the second non-memory transistor control line being connected to the first non-memory transistor and the second non-memory transistor respectively,
decrease a voltage level of the first non-memory transistor control line at a first time point within a first time period during which a program voltage is provided to a word line of the plurality of word lines, and
decrease a voltage level of the second non-memory transistor control line at a second time point within the first time period.

2. The nonvolatile memory device of claim 1, wherein:
the plurality of memory transistors are connected between a first node and a second node; and
the first non-memory transistor and the second non-memory transistor are connected between the first node and a first bit line.

3. The nonvolatile memory device of claim 2, wherein:
the first string includes a plurality of non-memory transistors connected between the first node and the first bit line; and
the first non-memory transistor and the second non-memory transistor are two adjacent non-memory transistors among the plurality of non-memory transistors.

4. The nonvolatile memory device of claim 3, wherein:
the first non-memory transistor includes a first terminal, a second terminal, and a third terminal,
the second non-memory transistor includes a fourth terminal, a fifth terminal, and a sixth terminal,
the first terminal is connected to the first non-memory transistor control line,
the fourth terminal is connected to the second non-memory transistor control line, and
the second terminal and the fifth terminal are connected through a third node.

5. The nonvolatile memory device of claim 2, wherein:
each non-memory transistor of the first non-memory transistor and the second non-memory transistor is one of a string selection transistor, a gate-induced drain leakage (GIDL) string selection transistor, and a dummy memory transistor.

6. The nonvolatile memory device of claim 2, comprising:
a page buffer circuit configured to provide a power supply voltage to the first bit line during the first time period.

7. The nonvolatile memory device of claim 1, wherein the row decoder is configured to:
decrease a voltage level of the first non-memory transistor control line from a first voltage to a second voltage at the first time point, and
decrease a voltage level of the second non-memory transistor control line from the first voltage to the second voltage at the second time point.

8. The nonvolatile memory device of claim 7, wherein the second voltage is a ground voltage.

9. The nonvolatile memory device of claim 8, wherein the row decoder is configured to float the first non-memory transistor control line at a third time point, the third time point being between the first time point and the second time point.

10. The nonvolatile memory device of claim 7, wherein:
after the second time point, the voltage level of the first non-memory transistor control line is decreased below the second voltage.

11. A nonvolatile memory device comprising:
an inhibit string connected to a plurality of word lines, a plurality of non-memory transistor control lines, and a first bit line;
a program string connected to the plurality of word lines, the plurality of non-memory transistor control lines, and a second bit line; and
a row decoder configured to decrease a voltage level of a victim non-memory transistor control line below a ground voltage at a first time point within a first time period, wherein the victim non-memory transistor control line is a non-memory transistor control line of the plurality of non-memory transistor control lines, and the first time period is a time period during which a program operation is performed on a target memory transistor included in the program string.

12. The nonvolatile memory device of claim 11, wherein the inhibit string includes:
a plurality of non-memory transistors connected in series between a first node and the first bit line, the plurality of non-memory transistors being configured to operate based on a plurality of voltage levels of the plurality of non-memory transistor control lines, respectively; and
a plurality of memory transistors connected in series between the first node and a second node, the plurality of memory transistors being configured to operate based on a plurality of voltage levels of the plurality of word lines, respectively.

13. The nonvolatile memory device of claim 12, wherein the row decoder is configured to:
decrease the voltage level of the victim non-memory transistor control line below the ground voltage based on controlling a voltage level of an aggressor non-memory transistor control line, wherein the aggressor non-memory transistor control line is a non-memory transistor control line of the plurality of non-memory transistor control lines.

14. The nonvolatile memory device of claim 13, wherein:
a first non-memory transistor which is connected to the aggressor non-memory transistor control line, and a victim non-memory transistor which is connected to the victim non-memory transistor control line are connected directly.

15. The nonvolatile memory device of claim 13, wherein the row decoder is configured to:
decrease the voltage level of the victim non-memory transistor control line from a first voltage to the ground voltage at a second time point prior to the first time point; and
decrease the voltage level of the aggressor non-memory transistor control line from the first voltage at the first time point.

16. The nonvolatile memory device of claim 15, wherein the row decoder is configured to float the victim non-memory transistor control line at a third time point, the third time point being between the first time point and the second time point.

17. An operation method of a nonvolatile memory device, the nonvolatile memory device being configured to program-inhibit a first string, the first string being connected to a bit line, a plurality of word lines, and a plurality of non-memory transistor control lines, wherein the operation method comprises:
setting up the bit line and the plurality of non-memory transistor control lines;
providing a program voltage to a target word line of the plurality of word lines;
reducing a voltage level of a victim non-memory transistor control line to a ground voltage, the victim non-memory transistor control line being a non-memory transistor control line of the plurality of non-memory transistor control lines; and
reducing a voltage level of an aggressor non-memory transistor control line to the ground voltage, the aggressor non-memory transistor control line being a non-memory transistor control line of the plurality of non-memory transistor control lines.

18. The operation method of claim 17, between reducing the voltage level of the victim non-memory transistor control line and reducing the voltage level of the aggressor non-memory transistor control line, comprising:
floating the victim non-memory transistor control line.

19. The operation method of claim 17, wherein:
the victim non-memory transistor control line is connected to a first non-memory transistor, and
the aggressor non-memory transistor control line is connected to a second non-memory transistor, the second non-memory transistor being connected to the first non-memory transistor directly.

20. The operation method of claim 19, wherein:
the first non-memory transistor and the second non-memory transistor are included in an upper peripheral area of the first string.
